(19) United States
(12) Patent Application Publication
(10) Pub. No.: US 2012/0176784 A1
(43) Pub. Date: Jul. 12, 2012

(54) LUMINOUS RETROFITTING DOOR

(75) Inventors: Donald A. Peifer, Mountain View, CA (US); Tom Quinn, Los Altos Hills, CA (US); Hai Dau, San Ramon, CA (US)

(73) Assignee: LUNERA LIGHTING INC., Redwood City, CA (US)

(21) Appl. No.: 13/231,263

(22) Filed: Sep. 13, 2011

Related U.S. Application Data
(60) Provisional application No. 61/431,647, filed on Jan. 11, 2011.

(51) Int. Cl. F21V 7/00; H05K 13/00; F21V 21/00

(52) U.S. Cl. 362/217.05; 362/217.15; 29/592.1

(57) ABSTRACT

A luminous retrofitting door for use in a troffer-style fixture is provided. A door having a frame operative to be mounted in a troffer is provided. The door may retain one or more optical components including, for example, a LED module, a light guide array, a diffuser, and a reflector, that combine to emit light in a uniform manner from the troffer.

### CROSS-REFERENCE TO RELATED APPLICATION

This application claims the benefit of previously filed U.S. Provisional Patent Application No. 61/431,647, filed Jan. 11, 2011, entitled “LED RETROFIT FOR FLUORESCENT TUBE FIXTURE,” which is incorporated herein in its entirety.

### BACKGROUND

Light fixtures provide a source of light to illuminate dark environments. In particular, many commercial buildings, offices, and garages can include light fixtures providing a large amount of light. Many of these light fixtures make use of long fluorescent light tubes, which can provide a uniform and omnidirectional light. For example, troffer-type fixtures may provide a rectangular box-like structure in which two or more fluorescent light tubes may be disposed to provide illumination.

With the evolution of LED technology, however, it may be desirable to use one or more LED modules to provide the light source in these environments. The light provided by a LED module, however, may not radiate in an omnidirectional manner like the light provided by a fluorescent tube. Therefore, simply replacing fluorescent light tubes with one or more LED modules may not provide light of similar quality and may instead be distracting or bothersome. Retrofitting the numerous existing fluorescent light tube-based fixtures may therefore require a more complex solution than simply replacing the light source within the fixture.

### SUMMARY

A luminous door for retrofitting a troffer-style fixture, and methods for constructing the door are provided.

A door having a frame sized to fit within the opening of a troffer-style light fixture is provided. The frame may impart some structural stiffness and rigidity to the door so as to support different components placed within the door. The frame can include at least one lip extending around a periphery of the frame along a plane co-planar with a ceiling or with a plane of an external periphery of the troffer such that one or more optical components placed in the frame can rest against the lip.

The frame can retain any suitable type of optical component. For example, the door can include a diffuser forming a planar component that fits within the frame and is supported by the lip. Moving away from the lip, a light guide array (LGA) or other component for redirecting light from a light source can be disposed adjacent to the diffuser in an overlapping relationship. The LGA can be constructed such that light entering the LGA is frustrated out of the LGA towards the diffuser.

Light can be provided to the LGA using any suitable light source within the frame. For example, a LED module can be disposed within the frame and aligned with the LGA to provide light to the LGA. In some cases, the LED module can provide light along an edge of the LGA (e.g., edge lighting). Alternatively, the LED module can be disposed to provide light directly onto a large planar surface of the LGA (e.g., a surface that is co-planar with the diffuser). Any suitable number of LED modules can be retained within the frame including, for example, LED modules along one or more edges or sides of the frame (e.g., hidden from view above a lip).

To improve the performance of the door, the door can include a reflective layer disposed over the LGA such that the LGA is between the reflective layer and the diffuser. In this manner, light emitted by the LED module that is frustrated by the LGA along the surface of the LGA that is opposite the diffuser may be reflected back by the reflector into the LGA and back towards the diffuser. In some cases, an additional layer of material forming a back plate may be disposed over the reflective layer, for example for structural or mechanical reasons. For example, a stiff material may be provided to increase the stiffness and resistance to bending or twisting of the door. As another example, a hard material may be provided to protect the reflective layer from debris that may fall into the troffer towards the door.

Because the door may be designed to replace a light-weight diffuser panel in existing troffer structures, the materials used for the door may be selected to limit the weight of the door. For example, the frame can be constructed from aluminum (e.g., rather than steel), and the back plate may be constructed from aluminum, a plastic, or carbon fiber. In addition, the door can be retained within the troffer using a same mechanism as the light-weight diffuser panel. For example, the door can include a tab forming a hinge coupled to one side of the door, and a movable clip operative to engage the troffer on an opposite side of the door. Because the door may serve to retrofit different styles of troffers, or troffers constructed using different standards, the door may include pre-defined holes to which the tabs and clips may be secured, where the holes correspond to different types or models of troffers that may be retrofit.

### BRIEF DESCRIPTION OF THE DRAWINGS

The above and other features of the present invention, its nature and various advantages will be more apparent upon consideration of the following detailed description, taken in conjunction with the accompanying drawings in which:

FIG. 1 is a schematic view of an illustrative fluorescent tube based troffer light fixture;

FIG. 2 is a schematic view of an illustrative troffer-style fixture in which LED modules replace fluorescent light tubes in accordance with some embodiments of the invention;

FIG. 3 is a flow chart of an illustrative process for retrofitting a fluorescent light tube based troffer-style fixture with LED modules;

FIG. 4 is a perspective view of a partially exploded illustrative door used to retrofit a troffer in accordance with some embodiments of the invention;

FIG. 5 is a perspective view of the illustrative door of FIG. 4 in accordance with some embodiments of the invention;

FIG. 6 is a view of a top of the illustrative door of FIG. 4 in accordance with some embodiments of the invention; and

FIG. 7 is a view of a bottom of the illustrative door of FIG. 4 in accordance with some embodiments of the invention.

### DETAILED DESCRIPTION

This is directed to a luminous door for retrofitting a troffer-style fixture.

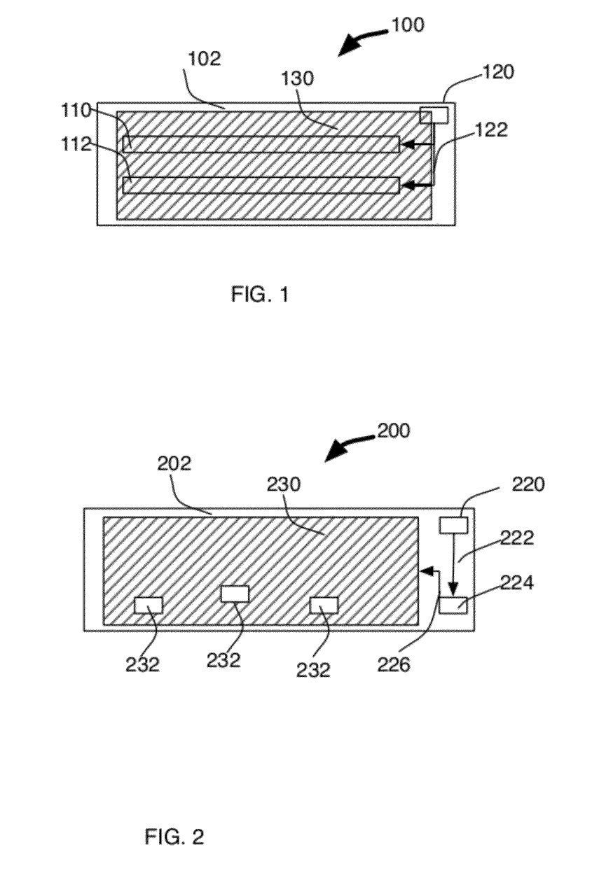

FIG. 1 is a schematic view of an illustrative fluorescent tube based troffer-style fixture. Fixture 100 can include body 102 defining a volume in which fluorescent tubes 110 and 112 are placed. Body 102 can include, for example, an open box shape having a planar back from which sidewalls extend. Tubes 110 and 112 can be mounted adjacent to the planar backplate, for example extending parallel to some of the sidewalls. Fixture 100 can include power supply 120 providing power to each of tubes 110 and 112 using conductive paths 122. In some cases, fixture 100 can instead or in addition include a ballast operative to transform or modify power received from an external source (e.g., power from a power line of a building in which fixture 100 is mounted).

To ensure that the light emitted from fixture 100 is uniform, fixture 100 can include diffuser 130 coupled to body 102 such that diffuser 130 is between tubes 110 and 112 and the environment that is illuminated by the fixture. For example, diffuser 130 can be disposed as a door closing the open box shape of body 102. Diffuser 130 can be provided within a frame that includes a coupling mechanism for connecting diffuser 130 to body 102. For example, a frame can include tabs and clips for mounting the frame and the diffuser as a door coupled to body 102. In some cases, diffuser 130 can include one or more cosmetic features for improving the appearance of fixture 100.

While fluorescent light tubes provide an omnidirectional and uniform light source, they may not be as efficient as other light sources. For example, fluorescent light tubes may require more power than LED modules. As another example, the lifespan of fluorescent light tubes may be far shorter than the lifespan of LED modules. It may therefore be less expensive, and more environmentally friendly to make use of LED modules as light sources for troffer-style fixtures instead of fluorescent light tubes.

Because fixtures such as fixture 100 are prevalent in many buildings, and have been a standard light fixture for many years, it may be cheaper and more efficient to retrofit the existing fixtures using LED modules as light sources rather than removing the existing fixtures and installing new fixtures that use LED modules. The light distribution of LED modules, however, may not be omnidirectional but rather Lambertian (in contrast with fluorescent tubes). Therefore, simply replacing fluorescent light tubes with an array of LED modules may not provide the same light distribution, and may therefore be an inadequate replacement.

It may be possible, however, to integrate LED modules with an LGA, a diffusive material, or another optical component such that the component can redirect light provided by the LED modules in a more uniformly distributed pattern. In addition, it may be possible to package the LED modules and optical components in such a manner as to retrofit existing troffers. FIG. 2 is a schematic view of an illustrative troffer-style fixture in which LED modules replace fluorescent light tubes in accordance with some embodiments of the invention. Fixture 200 can include some or all of the features of fixture 100 (FIG. 1). In some cases, fixture 200 can include body 202 and power supply 220 that are taken from an existing troffer-style fixture. In some cases, some or all of power supply 220 can be replaced to provide power that is more specifically tailored to LED modules (e.g., provide a new ballast).

Fixture 200 can include any suitable combination of LED modules and optical components to provide light using fixture 200. In particular, fixture 200 can include optical component 230 and LED modules 232 disposed such that LED modules 232 can provide light into optical component 230. LED modules 232 can be disposed in any suitable manner relative to optical component 230. In some cases, LED modules 232 can be integrated within optical component 230 (e.g., the optical component is constructed around the LED module, or the LED module is integrated between several layers of the optical component. Alternatively, LED modules 232 can be disposed adjacent to optical component 230 such that light from LED modules 232 is directed into optical component 230.

Fixture 200 can include any suitable number or type of LED modules 232. For example, fixture 200 can include one or more of high output LED modules, low output LED modules, and LED modules providing light in different colors. The LED modules can be disposed so that light provided by the LED modules may combine within optical component 230 to provide illumination from the fixture. In some cases, the particular number and type of LED modules can be selected based on characteristics of the troffer, or of the environment to be illuminated.

Optical component 230 can include any suitable combination of optical components. For example, optical component 230 can include one or more of a diffuser, a light guide array, a reflector, or any other such component. The components can be disposed so that they may combine to redirect light from LED modules 232 out of fixture 200 in a uniform and pleasing manner.

LED modules 232 can be powered using any suitable approach. In some embodiments, LED power supply or ballast 224 can interface with the original power supply 220 associated with the fluorescent light tubes. For example, conductive path 222 can connect power supply 220 to ballast 224, and conductive path 226 can connect ballast 224 to LED modules 232. In some cases, power supply 220 can instead be replaced with ballast 224 that corresponds to LED modules 232.

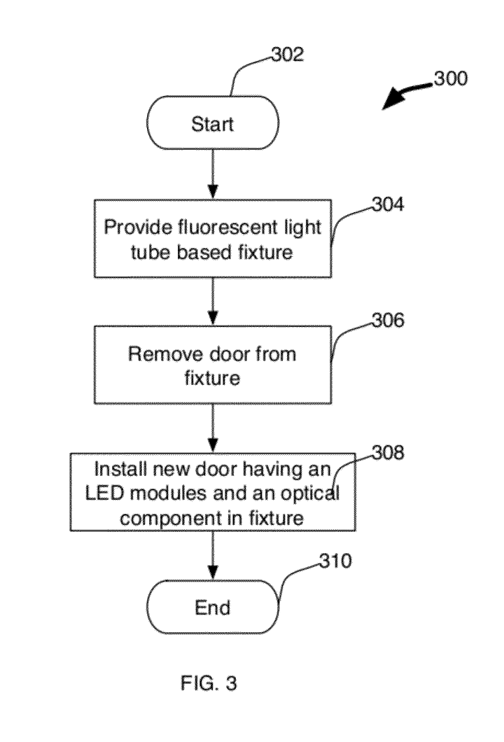

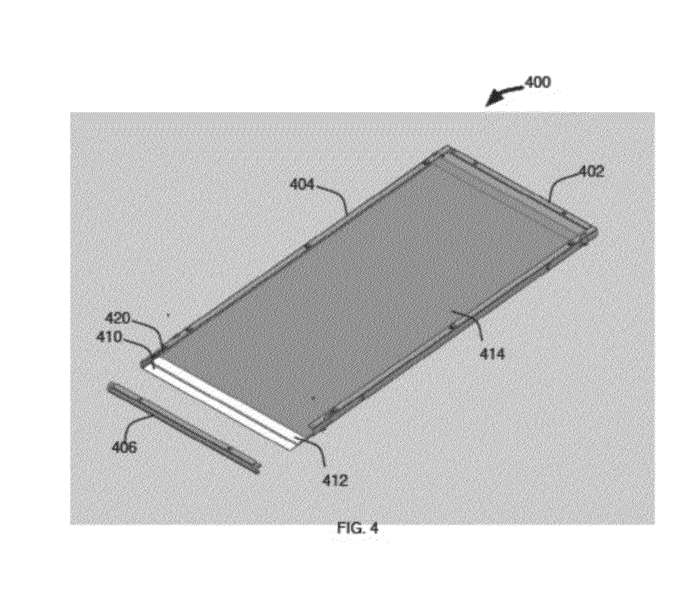

FIG. 3 is a flow chart of an illustrative process for retrofitting a fluorescent light tube based troffer-style fixture with LED modules. Process 300 can begin at step 302. At step 304, a fixture constructed for fluorescent light tubes can be provided. For example, a troffer-style fixture having terminals for receiving at least one fluorescent light tube can be provided. At step 306, the door of the fixture can be removed. For example, the fixture can be stripped to leave the body or base of the fixture such that a new door can be placed in the fixture. In some cases, one or more fluorescent light tubes enclosed within the fixture can be removed along with the door. In some cases, the power supply or ballast of the fixture can be removed and replaced. At step 308, a new door having an LED module and an optical component can be installed in the fixture. The new diffuser can be connected to the power supply of the fixture to provide power to the LED modules. Process 300 can end at step 310.

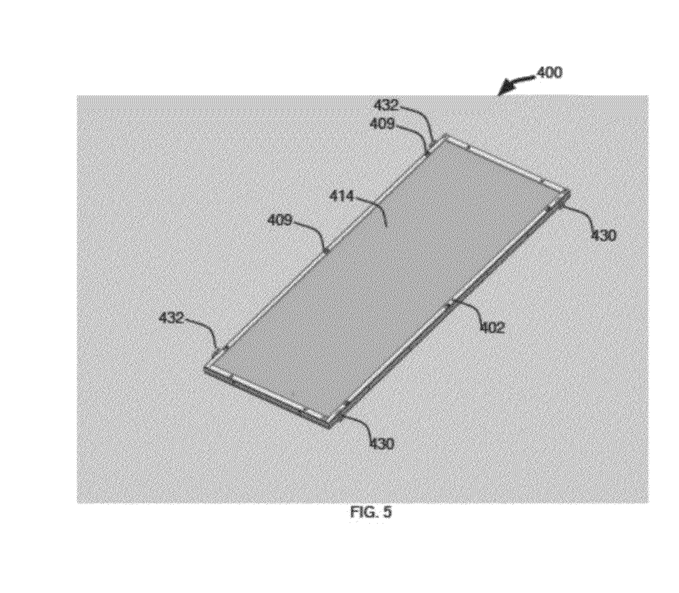

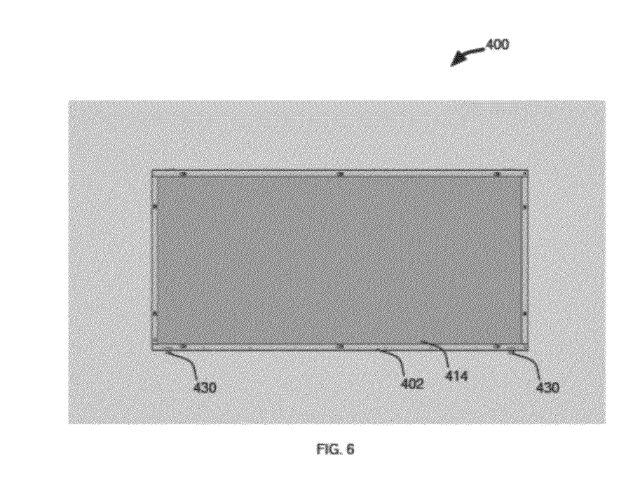

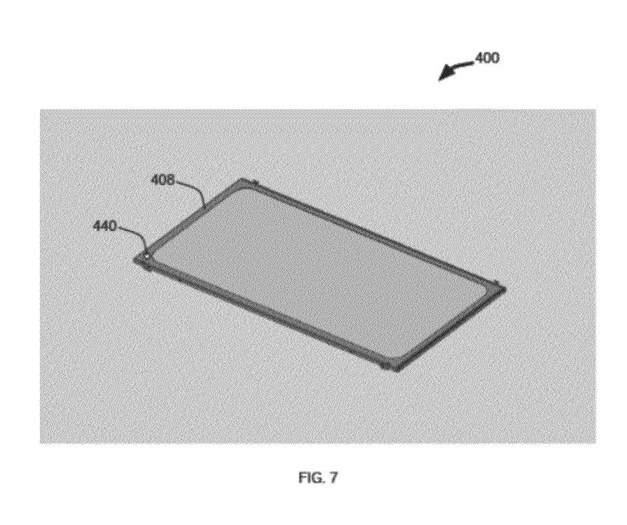

A more detailed implementation of a door having a LED module is now described in detail below. FIG. 4 is a perspective view of a partially exploded illustrative door used to retrofit a troffer in accordance with some embodiments of the invention. FIG. 5 is a perspective view of the illustrative door of FIG. 4 in accordance with some embodiments of the invention. FIG. 6 is a view of a top of the illustrative door of FIG. 4 in accordance with some embodiments of the invention. FIG. 7 is a view of a bottom of the illustrative door of FIG. 4 in accordance with some embodiments of the invention. Door 400 can include frame 402 operative to be secured within a fluorescent light tube troffer. For example, frame 402 can define a periphery of the door. Frame 402 can have any suitable shape and dimension including, for example, shapes and dimensions corresponding to existing or standard light fixtures (e.g., square, rectangular, polygonal, curved, or circular). For example, frame 402 can be rectangular and have a width of 2′ and a length of 4′. As another example, frame 402 can be rectangular and have a width of 2′ and a length of 8′. As still another example, frame 402 can be square and have a side length of 2′.

Frame 402 may secure one or more optical components for generating light to be emitted by door 400. For example, frame 402 may secure diffuser 410, light guide array 412 (LGA), and reflector 414 that combine to direct light from a light source. Each of diffuser 410, LGA 412, and reflector 414 may define a substantially planar component or sheet. The sheets of the diffuser, the LGA, and the reflector may be disposed adjacent to one another in an overlapping relationship such that the LGA is between the diffuser, which is exposed to the exterior of the troffer, and the reflector, which is disposed within the troffer. In this manner, light emitted by a LED module (described in more detail below) may be directed by LGA 412 out of the troffer. In particular, as light propagates through LGA 412, some light may escape LGA 412 towards diffuser 410, which may diffuse the light as it exits door 400. In addition, as light propagates through LGA 412, some light may escape LGA 412 towards reflector 414, which in turn may reflect the light back towards LGA 412 and diffuser 410.

Diffuser 410 can be constructed from any material suitable for diffusing light. For example, diffuser 410 can be constructed from plastic, acrylic, or glass. In some cases, diffuser 410 can include one or more coatings or other treatments for modifying or enhancing the optical properties of diffuser 410. For example, diffuser 410 can include a smooth inner surface and a smooth outer surface (e.g., in contrast with egg-carton shaped outer surface of diffusers typically used with fluorescent tube troffers). In some cases, diffuser 410 can have a particular treatment to provide a desired cosmetic effect (e.g., a smooth door). The cosmetic effect may enable branding by differentiating a retrofitted door from a standard fluorescent tube troffer.

LGA 412 can be constructed from any material suitable for redirecting light. For example, LGA 412 can include a slab or planar waveguide, a rib waveguide, or any other type of waveguide. In some cases, LGA 412 can include several guides combining to redirect light from a LED module. LGA 412 can be constructed from any suitable material including, for example, acrylic, plastic, or any other transparent or translucent material.

Reflector 414 can be constructed from a material that has high reflectivity. For example, reflector 414 can include a mirror, a polished metal, or another reflective surface. Reflector 414 can be constructed as a separate component, or can instead including a coating or sheet adhered to a surface of LGA 412. In some cases, reflector 414 can instead be provided on a surface of a backing sheet of the door (e.g., with an intermediate padding between the two).

To ensure proper operation of door 400, it may be necessary for door 400 to resist bending or twisting when it is installed in a troffer. In particular, reflector 414 may create artifacts or become visible if it bends or twists once door 400 is installed. One approach may be to increase the strength of frame 402, but this approach may increase the weight of door 400 by more than a desired amount (e.g., the weight of the door may reach a mechanical limit of tabs and clips used to retain the door). One approach for providing structural rigidity while maintaining low weight can include providing a backing sheet above the reflector within frame 402. The backing sheet can be sufficiently rigid to resist bending or torsion when door 400 is mounted in the troffer. The backing sheet can be constructed from any suitable material including, for example, a metal (e.g., steel, titanium, or aluminum), a plastic, a composite material, carbon fiber, or any other material having an adequate combination of stiffness and low weight).

Each of the diffuser, LGA, and reflector can have any suitable dimension. In some cases, each of diffuser 410, LGA 412, and reflector 414 can have the same dimensions so that light propagating through LGA 412 may reach one of diffuser 410 and reflector 414. The dimensions for the diffuser, LGA, and reflector can be selected relative to dimensions of frame 402. For example, diffuser 410 may be sized such that it rests against a bezel or lip 408 of frame 402. Lip 408 may have any suitable width including, for example a minimum width required to support diffuser 410. In some cases, lip 408 may be sized so as to prevent visible scalloping of light emitted by distinct LED packages into LGA 412. Lip 408 can extend from a sidewall of the frame, where mounting brackets or other components are coupled to the sidewall. Lip 408 can be disposed in a plane that is co-planar with the ceiling, or co-planar with a planar backplate of the troffer.

To retain diffuser 410, LGA 412, and reflector 414 within frame 402, frame 402 may include a movable side 406 that may be coupled to U-shaped primary frame 404. Diffuser 410, LGA 412, and reflector 414 may be slid into primary frame 404 adjacent to lip 408 through the opening left by movable side 406. Once the optical components have been placed within primary frame 404, movable side 406 can be secured to primary frame 404 to close frame 402 and maintain the optical components within the frame. In some cases, movable side 406 may include a sidewall but no lip, which primary frame 404 can include a sidewall extending in a U-shape and a lip forming a ring extending all the way around frame 402. In this manner, there may be no break or other non-aesthetic artifact on the portion of frame 402 that is visible when door 400 is installed.

Different approaches can be used to maintain the position of the diffuser, LGA, and reflector within frame 402. In some cases, primary frame 404 can include an extension that is parallel to lip 408 such that lip 408 and the extension are offset from one another, and portions of the diffuser, LGA, and reflector are between lip 408 and the extension. The extension can include one or more tabs 409 extending towards the diffuser, LGA, and reflector such that tabs 409 come into contact with the reflector and compress the reflector, LGA and diffuser towards lip 408.

To reduce the weight of door 400, while still providing stiffness and strength to support the diffuser, LGA, and reflector, frame 402 can be constructed from a light-weight but strong material. For example, frame 402 can be constructed from a metal (e.g., aluminum or titanium), a plastic, a composite material, or a ceramic material. In some cases, the particular material used for frame 402 can instead or in addition be selected based on cost considerations and on ease of manufacturing considerations. Other factors may be considered to select the material used for frame 402 including, for example, flame resistance.

Door 400 can include one or more LED modules for emitting light to be transmitted by the door. In some cases, door 400 can include LED module 420 positioned along an edge of frame 402. For example, an LED module having a row of LED packages may be disposed along a long edge of frame 402 to provide edge-lighting for LGA 412 and to propagate light through door 400. In some cases, door 400 can instead or in addition include other LED modules disposed along other edges of frame 402 (e.g., two LED modules disposed on opposite edges of frame 402, or two LED modules disposed on adjacent edges of frame 402). Each LED module can include any suitable number or type of LED packages including, for example, LED packages having a particular luminosity, color, power, or combinations of these.

LED modules may generate heat, which may need to be dissipated to optimize the performance of door 400. In some cases, door 400 can include a heat sink placed adjacent to LED module 420. For example, door 400 may include a heat sink between LED module 420 and frame 402. In addition, because frame 402 may be constructed from a metal (e.g., aluminum or steel), heat may transfer from the heat sink to frame 402 to further dissipate heat using the entire door 400.

Because door 400 is constructed to retrofit existing troffer-style fixtures, door 400 can be mounted to a troffer using a similar approach to that used for a diffuser previously provided in a troffer. In particular, the door can be mounted using tabs 430 on one side of the frame to serve as a hinge, and clips 432 on an opposite side of the frame to secure the door “closed” in the troffer. In some cases, frame 402 can include pre-tapped holes for assembling a securing mechanism (e.g., a tab and clip) for mounting door 400. In this manner, a door can be retrofitted in any of several standard troffers by disposing the tabs and clips in appropriate positions.

Door 400 may be powered using any suitable approach. In some cases, wires or other electrical connectors from LED module 420 can be connected directly to a power supply of the troffer that is retrofit. In some cases, the power supply or ballast of the troffer can be removed and replaced with a ballast designed to provide proper amounts of power to LED module 420. In some cases, it may not even be necessary to remove existing fluorescent light tubes previously present in a troffer when door 400 is installed. Instead, the power supply to the tubes may be removed, and power instead provided to LED modules 420. This may provide an initial cost savings by eliminating an immediate need to recycle or otherwise dispose of the fluorescent light tubes.

Any suitable approach can be used to control door 400. For example, an existing wired control solution (e.g., a light switch) associated with the troffer can be used to turn on and off door 400. Alternatively, door 400 can include one or more sensors operative to receive commands or instructions for controlling the operation of door 400. For example, lip 408 can include opening or window 440 through which signals may pass. For example, window 440 can be constructed to enable instructions provided using IR, RF, NFC, ZigBee®, BlueTooth®, or any other suitable wireless communications protocol. A control module associated with the sensor can be provided within door 400, as part of a ballast associated with door 400, or both.

It is to be understood that the steps shown in process 300 of FIG. 3 are merely illustrative and that existing steps may be modified or omitted, additional steps may be added, and the order of certain steps may be altered. Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The above-described embodiments of the invention are presented for purposes of illustration and not of limitation.

What is claimed is:

1. A luminous retrofitting door for use in a troffer-style light fixture, comprising:
a frame defining a rectangular periphery of the door, the frame comprising a lip;
a LED module positioned adjacent to a first side of the frame, the LED module oriented towards a side of the frame opposite the first side;
a diffuser forming a sheet mounted in the frame, the diffuser resting adjacent to the lip; and
a light guide array aligned with the LED module, the light guide array placed adjacent to the diffuser.

2. The luminous retrofitting door of claim 1, further comprising:
a reflective layer disposed adjacent to the light guide array, wherein the light guide array is between the reflective layer and the diffuser.

3. The luminous retrofitting door of claim 2, further comprising:
a backing sheet disposed adjacent to the reflective layer, wherein the reflective layer is disposed between the light guide array and the backing sheet.

4. The luminous retrofitting door of claim 3, wherein:
the backing is constructed from at least one of:
a metal;
a plastic;
a composite material; and
a carbon fiber based material.

5. The luminous retrofitting door of claim 1, wherein:
the light guide array forms a sheet; and
the sheet of the light guide array overlaps with the sheet of the diffuser.

6. The luminous retrofitting door of claim 1, further comprising:
at least one tab coupled to the frame; and
at least one clip coupled to the frame, wherein the at least one tab and the at least one clip engage the troffer-style light fixture.

7. The luminous retrofitting door of claim 6, further comprising:
a first set of pre-defined holes in the frame for coupling the at least one tab to the frame; and
a second set of pre-defined holes in the frame for coupling the at least one clip to the frame.

8. The luminous retrofitting door of claim 6, wherein:
the at least one tab and the at least one clip are coupled to opposite sides of the frame.

9. The luminous retrofitting door of claim 1, further comprising:
a ballast coupling the LED module to a power supply of the troffer-style light fixture.

10. A method for providing a luminous door in a fluorescent light tube troffer, comprising:
providing a fluorescent light tube troffer forming a light fixture, wherein the fluorescent light tube troffer comprises a door with an initial diffuser;
removing the door with the initial diffuser; and
installing a replacement door comprising a LED module, a light guide array, and a diffuser instead of the removed door; and
providing power to the replacement door.

11. The method of claim 10, further comprising:
installing a replacement ballast in the fluorescent light tube troffer; and
coupling the replacement ballast to the LED module.

12. The method of claim 10, further comprising:
identifying positions of openings for at least one tab and at least one clip in the fluorescent light tube troffer; and
coupling at least one tab and at least one clip to the replacement door at locations corresponding to the identified positions.

13. The method of claim 12, wherein coupling further comprises:
coupling the at least one tab and the at least one clip to the replacement door at pre-defined locations.

14. The method of claim 13, wherein:
the pre-defined locations comprise pre-tapped holes.

15. The method of claim 10, further comprising:
removing existing fluorescent light tubes from the fluorescent light tube troffer.

16. A structure for retrofitting an existing fluorescent light tube troffer, comprising:
a primary frame defining a U-shape, the primary frame comprising three connected sidewall segments and a lip extending perpendicular from the sidewall segments;
a movable frame operative to be coupled to the primary frame to form an assembled frame defining a closed loop, the movable frame comprising a sidewall;
a LED module disposed adjacent to one of the sidewall segments;
at least one optical component disposed adjacent to the LED module and resting on the lip, wherein light from the LED module is operative to be redirected by the at least one optical component out of a plane defined by the lip; and
a power supply connecting the LED module to an existing power supply of the troffer.

17. The structure of claim 16, wherein:
the lip defines a closed loop around a periphery of the assembled frame.

18. The structure of claim 16, wherein the at least one optical component comprises at least one of:
a diffuser;
a light guide array; and
a reflector.

19. The structure of claim 18, wherein:
the at least one optical component comprises at least two distinct components; and
the two distinct components each have rectangular profiles having substantially the same dimensions.

20. The structure of claim 16, further comprising:
at least two tabs; and
at least two clips, wherein the at least two tabs and the at least two clips are operative to engage the troffer.
